(19) United States
(12) Patent Application Publication
(10) Pub. No.: US 2008/0116454 A1
(43) Pub. Date: May 22, 2008

(54) Photodiode Having Hetero-Junction Between Semi-Insulating Zinc Oxide Semiconductor Thin Film And Silicon

(75) Inventor: Katsuya Shimizu, Kyoto (JP)

Correspondence Address: RADER FISHMAN & GRAUER PLLC, LION BUILDING, 1233 20TH STREET N.W., SUITE 501, WASHINGTON, DC, 20036, US

(73) Assignee: Kodenshi Corporation, Kyoto (JP)

(21) Appl. No.: 11/795,802

(22) PCT Filed: Jun. 16, 2005
(86) PCT No.: PCT/JP05/11047

§ 371 Date: Jul. 23, 2007

(30) Foreign Application Priority Data
Jan. 25, 2005 (JP) 2005-016555

(51) Int. Cl. H01L 31/0264

(52) U.S. Cl. 257/43; 257/E31.004

(57) ABSTRACT

A photodiode which eliminates sensitivity reduction in a short wavelength region such as blue, an unavoidable problem posed by doping, resolves response reduction by the scattering of acceptor ions or impurities due to doping of impurities at the same time, and has very high sensitivity and fast response in a UV-IR range. A photodiode having a hetero-junction between a semi-insulating zinc oxide semiconductor thin film and silicon and comprising, basically, n-type silicon (1) and a semi-insulating zinc oxide semiconductor thin film (3) formed on the n-type silicon, characterized in that the n-type silicon forms a cathode region, and the formation of a semi-insulating zinc oxide semiconductor thin film produces a p-type inversion layer (4) at the upper portion of the n-type silicon in contact with the semi-insulating zinc oxide semiconductor thin film, the p-type inversion layer forming a photo-detection region and an anode region.

### TECHNICAL FIELD

The present invention relates to a photodiode having a novel structure, more particularly to a photodiode having a light-receiving region formed by a hetero-junction between a semi-insulating zinc oxide semiconductor thin film and silicon irrespective of whether the silicon is n-type or p-type.

### BACKGROUND ART

With the coming of advanced information society, the amount of information transmitted and stored is steadily increasing, and the speed of information transmission is also increasing every year. Under the circumstances, along with the widespread use of DVD, an optical device, which is an important key device for DVD, using a blue laser instead of a red laser has passed through a study phase and is then coming into practical use to support DVD having a higher density, such as high definition DVD.

The wavelength of laser light used for such DVD is a blue-violet wavelength (405 nm). Along with the practical use of a blue laser, it is absolutely necessary to enhance the performance of alight-receiving device for sensing a blue laser. At present, a photodiode is basically used as a light-receiving device for receiving light ranging from blue to infrared or as a light-receiving device for an integrated circuit. A conventional photodiode basically has a pn-junction formed by doping with p-type or n-type impurities by diffusion or ion implantation.

A blue laser is almost absorbed by the time when it reaches a depth of about 1000 Å from the surface of a silicon substrate. Therefore, in the case of a photodiode using n-type silicon and having a p-type region doped with p-type impurities, in order to improve sensitivity to light having a short wavelength of blue light or less, it is necessary to make the concentration of the p-type impurities in the p-type region not too high and to make a junction depth very shallow to increase the lifetime of carriers. However, in a case where a junction having a shallow junction depth is formed using a p-type region doped with impurities whose concentration is not too high, the resistance of the surface of a silicon substrate is increased, thereby causing a big problem that response slows down due to an increase in a CR-time constant.

On the other hand, in a case where a p-type region doped with a high concentration of impurities is formed to suppress such resistance increase, another problem that the lifetime of carriers is shortened occurs, thereby significantly reducing sensitivity to light having a short wavelength, such as blue light. In addition, carriers are scattered by acceptor ions generated by high concentration impurity doping, and therefore the mobility of the carriers is reduced and then response slows down. For these reasons, in the case of a conventional impurity-doped photodiode, the fact is that an attempt to find a compromise between a junction depth and the concentration of impurities for doping has been made. Further, when such a conventional impurity-doped photodiode is irradiated with infrared light, it is inevitable that the mobility of carriers is reduced by impurity doping, which poses limitations on the frequency response characteristics of the photodiode. The same goes for a photodiode using p-type silicon and having an n-type region doped with n-type impurities.

Patent Document 1: Japanese Patent Application Laid-open No. 2004-087979

Patent Document 2: Japanese Patent Application Laid-open No. H9-237912

### DISCLOSURE OF THE INVENTION

As described above, a conventional impurity-doped photodiode has an unavoidable problem associated with impurity doping, that is, a problem of reduction in sensitivity to light having a short wavelength range, such as blue light. In addition, such a conventional impurity-doped photodiode also has a problem of reduction in response speed due to the scattering of carriers by ions generated by impurity doping. It is therefore an object of the present invention to simultaneously solve the above problems and to provide a photodiode having both a very high sensitivity to light ranging from ultraviolet to infrared and a high response speed.

In order to achieve the above object, the present invention is directed to a photodiode having a hetero-junction between a semi-insulating zinc oxide semiconductor thin film and silicon, comprising:

n-type silicon; and

a semi-insulating zinc oxide semiconductor thin film formed on the n-type silicon, wherein the n-type silicon serves as a cathode region and includes, in the upper part thereof, a p-type inversion layer formed by the contact between the n-type silicon and the semi-insulating zinc oxide semiconductor thin film formed on the n-type silicon, wherein the p-type inversion layer serves as a light-receiving region and an anode region.

In the present invention, it is preferred that the p-type inversion layer as a light-receiving region has an overlapping area with a p-type impurity-doped region which serves as an ohmic region for the light-receiving region.

Further, in the present invention, it is also preferred that the semi-insulating zinc oxide semiconductor thin film is partially composed of low-resistance zinc oxide, and that the low-resistance zinc oxide is connected to the p-type impurity-doped region via an electrode formed for the low-resistance zinc oxide.

Another aspect of the preset invention is directed to a photodiode having a hetero-junction between a semi-insulating zinc oxide semiconductor thin film and silicon, comprising:

p-type silicon; and

a semi-insulating zinc oxide semiconductor thin film formed on the p-type silicon, wherein the p-type silicon and the semi-insulating zinc oxide semiconductor thin film form a hetero-junction therebetween which serves as a light-receiving region, wherein the light-receiving region has an overlapping area with an n-type impurity-doped region formed in the p-type silicon to extract a photocurrent therefrom.

The photodiode according to the present invention having such a structure described above has the following effects. The photodiode according to the present invention using n-type silicon and having a p-type inversion layer formed by forming a semi-insulating zinc oxide semiconductor thin film on the n-type silicon can excellently and simultaneously solve two problems of a conventional impurity-doped photodiode, that is, a problem of reduction in sensitivity to light, especially light having a short wavelength of blue light or less and a problem of reduction in response speed. When a photodiode having a silicon substrate is irradiated with light having a shorter wavelength, the light is absorbed by a portion nearer to the surface of the silicon substrate. For example, when the photodiode is irradiated with a blue-violet laser having a wavelength of 400 nm, 63% of the blue-violet laser is absorbed by the time when it reaches a depth of about 1,300 Å, which is an absorption length for light having a wavelength of 400 nm, from the surface of the substrate. Therefore, a photodiode for blue light needs to have a junction depth of 1,000 Å or less, whereas the junction depth of a photodiode for light having a relatively long wavelength, such as red light, is about 1 micron.

A conventional impurity-doped photodiode needs to have a shallow junction depth to improve sensitivity to light having a short wavelength of blue light or less. In addition, it is also necessary to make the concentration of impurities for doping not too high to prevent a reduction in sensitivity due to recombination of carriers and to increase the lifetime of the carriers. However, such a shallow junction formed by doping with impurities whose concentration is not too high causes an increase in resistance value, which increases a CR-time constant and therefore slows down response. In order to achieve fast response, it is necessary to form a p-type region doped with a high concentration of impurities. This, however, significantly shortens the lifetime of carriers generated in the high-concentration impurity region near the surface of a substrate, thus resulting in a reduction in sensitivity to light having a short wavelength. In addition, doping with a high concentration of impurities causes scattering of the carriers by acceptor ions. This reduces the mobility of the carriers and therefore slows down response, thus resulting in deteriorated frequency characteristics. After all, it is necessary to find a compromise between sensitivity to light having a short wavelength and response speed which are contradictory matters. However, it is very difficult to achieve both a high sensitivity to light having a short wavelength, such as a blue laser, and a high response speed.

According to the present invention, the zinc oxide layer formed on the n-type silicon is transparent to light having a wavelength longer than a band edge wavelength (375 nm), such as blue light. Further, since the p-type inversion layer as a p-type region is formed in the uppermost part of the n-type silicon due to valence band discontinuity between zinc oxide and silicon, the light-receiving region is not doped with any p-type impurities, thereby significantly increasing the lifetime of carriers generated by light. Such an increased lifetime of carriers and a very shallow junction depth of 100 Å or less make it possible for the photodiode according to the present invention to have a high sensitivity also to light having a short wavelength, such as blue light.

Further, as described above, since the light-receiving region of the photodiode according to the present invention is not doped with any p-type impurities, scattering of carriers by acceptor ions does not occur at all, and therefore holes are present in a two-dimensionally limited area having a depth of 100 Å or less. This allows the holes to behave like two-dimensional holes so that fast response is achieved. The photodiode according to the present invention has a high sensitivity also to light having a long wavelength in its deep region in the silicon substrate as in the case of a conventional impurity-doped photodiode, but conduction in the p-type inversion layer is carried out by holes behaving like two-dimensional holes so that fast response is achieved (It is to be noted that electrons which are confined in a potential well, having a depth of about de Broglie wavelength of about 100 Å, and which have a limited two-dimensional degree of freedom are generally called “two-dimensional electrons, and such two-dimensional electrons are applied to high-electron-mobility transistors (HEMTs) because they are generated in a high-resistance layer and therefore scattering by impurities can be suppressed. In a case where carriers are holes, holes are called “two-dimensional holes”.). Further, it is usually difficult for silicon to perform photoelectric conversion under irradiation with ultraviolet light having a wavelength shorter than a band edge wavelength (375 nm), but the photodiode according to the present invention can efficiently perform photoelectric conversion even under irradiation with ultraviolet light because the zinc oxide layer absorbs ultraviolet light.

In the photodiode according to the present invention having a p-type inversion layer, the semi-insulating zinc oxide is insulating, and therefore there is a case where the p-type inversion layer is destabilized by polarization charge. The destabilization of the p-type inversion layer due to polarization can be prevented by partially reducing the resistance of the semi-insulating zinc oxide and connecting the low-resistance portion of the semi-insulating zinc oxide with the p-type inversion layer via a p-type impurity-doped region.

On the other hand, in the case of a photodiode according to the present invention including p-type silicon and a semi-insulating zinc oxide semiconductor, it can be considered that a hetero-junction between the p-type silicon and the semi-insulating zinc oxide semiconductor forms an n-type channel layer in the lower part of the semi-insulating zinc oxide semiconductor, and the p-type silicon and the n-type channel layer impart photodiode characteristics to the photodiode. Also in the case of the photodiode using p-type silicon, the light-receiving region is not doped with any n-type impurities. Therefore, as in the case of the photodiode using n-type silicon, the photodiode using p-type silicon also has a high sensitivity and excellent frequency characteristics.

As has been described above, according to the present invention, it is possible to simultaneously solve two problems of a conventional impurity-doped photodiode associated with impurity doping, that is, a problem of reduction in sensitivity to light having a short wavelength and a problem of reduction in response speed, and therefore to provide a photodiode having a high sensitivity to light having a wavelength in a wide range from ultraviolet to infrared, a high response speed, and excellent frequency characteristics.

### BRIEF DESCRIPTION OF THE DRAWINGS

FIG. 1A is a cross-sectional view which schematically shows a photodiode according to a first embodiment of the present invention;

FIG. 1B is an enlarged cross-sectional view of a part A shown in FIG. 1A;

FIG. 2A shows a band structure of a semi-insulating zinc oxide semiconductor and silicon before contact;

FIG. 2B shows a band model of the semi-insulating zinc oxide semiconductor and the silicon after contact;

FIG. 2C is an enlarged schematic view of a part B shown in FIG. 2B;

FIGS. 3A to 3C are schematic cross-sectional views which illustrate a process for producing the photodiode according to the first embodiment of the present invention;

FIG. 4 is a graph which shows an example of a photoluminescence spectrum of zinc oxide used in the present invention;

FIG. 5 is a graph which shows an example of an X-ray diffraction pattern of zinc oxide used in the present invention;

FIG. 6A is a graph which shows an example of characteristics of the photodiode according to the first embodiment of the present invention;

FIG. 6B is a schematic view for explaining a method for measuring the characteristics shown in FIG. 6A;

FIG. 7 is a graph which shows an example of spectral sensitivity characteristics of the photodiode according to the present invention;

FIG. 8A is a cross-sectional view which schematically shows a photodiode according to a second embodiment of the present invention;

FIG. 8B is a partially cut-away plan view which schematically shows the photodiode shown in FIG. 8A;

FIG. 8C is an enlarged cross-sectional view of a part C shown in FIG. 8A, which schematically shows the operation of the photodiode shown in FIG. 8A;

FIG. 9 is a graph which shows an example of frequency characteristics of the photodiode according to the second embodiment of the present invention;

FIG. 10 is a cross-sectional view which schematically shows a photodiode according to a third embodiment of the present invention;

FIG. 11 is a cross-sectional view which schematically shows a photodiode according to a fourth embodiment of the present invention;

FIG. 12A is a cross-sectional view which schematically shows a photodiode according to a fifth embodiment of the present invention;

FIG. 12B is a graph which shows an example of characteristics of an n-type channel layer shown in FIG. 12A;

FIG. 12C is a schematic view for explaining a method for measuring the characteristics shows in FIG. 12B; and

FIG. 12D is a graph which shows an example of characteristics of the photodiode according to the fifth embodiment of the present invention under irradiation with a blue laser.

### BEST MODE FOR CARRYING OUT THE INVENTION

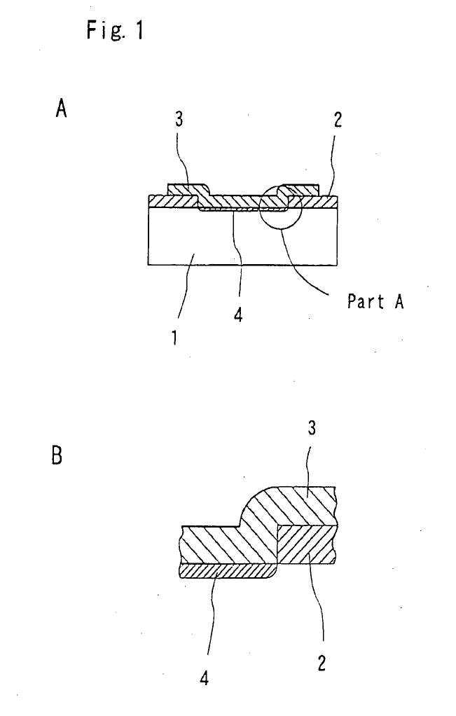

Hereinbelow, a photodiode according to the present invention having a p-type inversion layer provided by forming a semi-insulating zinc oxide semiconductor thin film will be described in detail with reference to specific embodiments shown in the accompanying drawings. FIG. 1A is a cross-sectional view which schematically shows a photodiode according to a first embodiment of the present invention having a p-type inversion layer, and FIG. 1B is an enlarged view of a part A shown in FIG. 1A. As shown in FIG. 1A, the photodiode according to the present invention has a structure in which an excellent semi-insulating zinc oxide semiconductor thin film 3 (hereinafter, abbreviated as a “semi-insulating ZnO thin film 3”) is formed on n-type silicon 1 by using patterned silicon dioxide 2 as a mask. Such a very simple structure makes it possible to form a p-type inversion layer 4 in the upper part of the n-type silicon 1 which is in contact with the semi-insulating ZnO thin film 3, and the p-type inversion layer 4 serves as a light-receiving region. As shown in FIG. 1B, the p-type inversion layer 4 serving as a light-receiving region is formed on the n-type silicon 1 side of a boundary surface between the semi-insulating ZnO thin film 3 and the n-type silicon 1 due to the effect of the semi-insulating ZnO thin film 3.

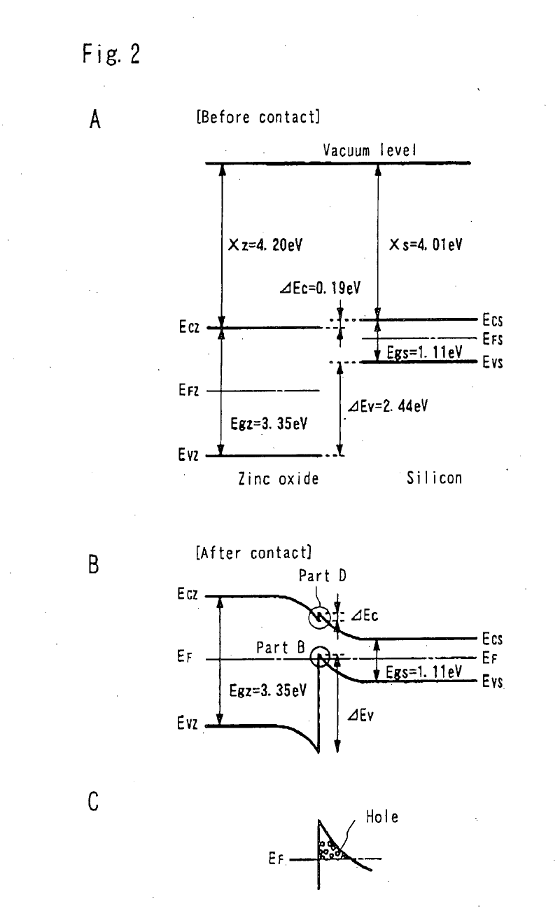

The mechanism of formation of the p-type inversion layer 4 serving as a light-receiving region will be described with reference to possible band models shown in FIG. 2. FIG. 2A is an energy level diagram between the zinc oxide semiconductor and the n-type silicon doped with a small amount of impurities and having a high specific resistance at the time when they are separated from each other. As can be seen from FIG. 2A, there is an energy difference (ΔEc) of 0.19 eV between the bottom of conduction band of zinc oxide (E_{cz}) and that of silicon (E_{cs}), and there is a very large energy difference (ΔEv) of 2.44 eV between the top of valence band of zinc oxide (E_{vz}) and that of silicon (Eᵥₛ). FIG. 2B shows an energy band model between the zinc oxide semiconductor and the n-type silicon after when they are in contact with each other. According to the teaching of semiconductor physics, after zinc oxide and silicon are brought into contact with each other, the Fermi level of zinc oxide (E_{FZ}) coincides with the Fermi level of silicon (E_{FS}) so that zinc oxide and silicon have the same Fermi level (E_{F}). Therefore, band discontinuities occur according to the difference in electron affinity between zinc oxide (X_{z}) and silicon (Xₛ) and by the difference in band gap energy between zinc oxide (E_{gz}) and silicon (E_{gs}). These band discontinuities correspond to ΔEc and ΔEv shown in FIG. 2B, and ΔEc and ΔEv are equal to values shown in FIG. 2A. It can be considered that these values are actually influenced by an interface state depending on the conditions of the interface between zinc oxide and silicon. However, the energy band model shown in FIG. 2 does not take the influence of the interface state into consideration.

It can be considered that an energy band (Eᵥₛ) at the top of the silicon valence band largely bends upward due to a very large difference between the energy of top of the valence band of zinc oxide and that of silicon (ΔEᵥ), and therefore the n-type silicon is inverted to p-type silicon. As a result, as shown in FIG. 2C that is an enlarged view of a part B shown in FIG. 2B, holes can be accumulated. In this case, unlike an MOS in which inversion is electrostatically achieved by application of a bias voltage across an oxide film, inversion is achieved by band discontinuity, and therefore the holes can constantly exist without the necessity of application of a bias voltage. However, in order to provide such a p-type inversion layer, is it necessary to directly form a zinc oxide semiconductor thin film on silicon to form a hetero-junction therebetween, which is not easy.

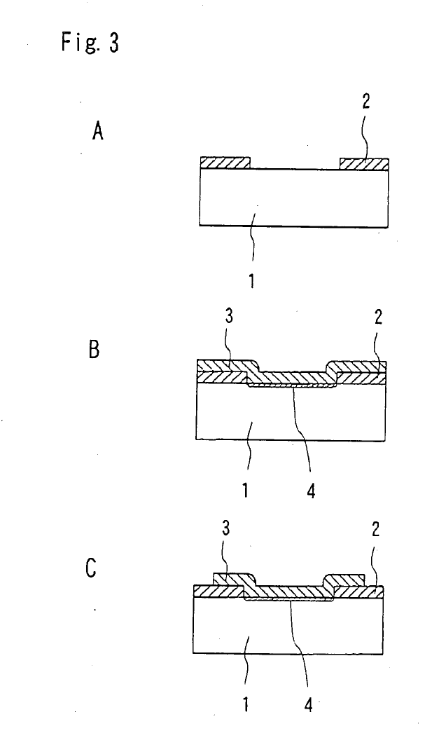

FIGS. 3A to 3C schematically show the process of producing the photodiode according to the first embodiment of the present invention shown in FIG. 1. First, an oxide film 2 is formed on an n-type silicon substrate 1 in the same manner as in a conventional method for producing a semiconductor device, and then a portion corresponding to a p-type region serving as a light-receiving region is subjected to pattern etching (see FIG. 3A). Next, the surface of the wafer is washed, and then a semi-insulating ZnO thin film 3 is formed on the entire surface of the wafer (see FIG. 3B). This step of forming a zinc oxide semiconductor thin film is very important, and therefore will be described in detail below. It is conventionally known that zinc oxide has piezoelectric effect, and it is suggested that zinc oxide has potential for use in ultraviolet LEDs and exciton lasers. Therefore, zinc oxide is being actively studied as an important material for a next-generation light emitting semiconductor device by various research institutes. However, formation of a zinc oxide semiconductor thin film, which can exhibit band edge PL emission, on silicon has been considered very difficult. This is because it is necessary to make a growth temperature high to obtain good crystallinity (e.g., 600° C. or higher). This, however, promotes not only the oxidation of a silicon surface but also the occurrence of transition due to lattice distortion, and therefore it is impossible to grow a good crystalline film. In order to solve such a problem, an attempt to grow zinc oxide on a buffer layer, formed on silicon so as to play a role as an interlayer, has been generally made (see, for example, Japanese Patent Application Laid-open Nos. 2001-44499 and 2003-165793). In this case, a silicon nitride film or a calcium fluoride film is provided at the interface between silicon and zinc oxide, which is not preferred from the viewpoint of utilizing the properties of a hetero-junction between silicon and zinc oxide. Under the circumstances, a device using a zinc oxide/silicon hetero structure is not yet in practical use.

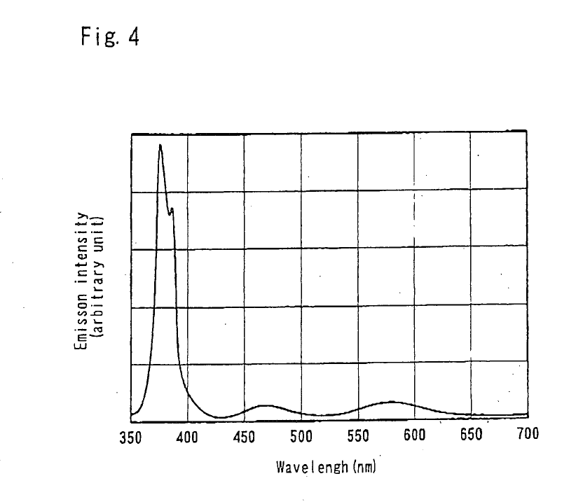

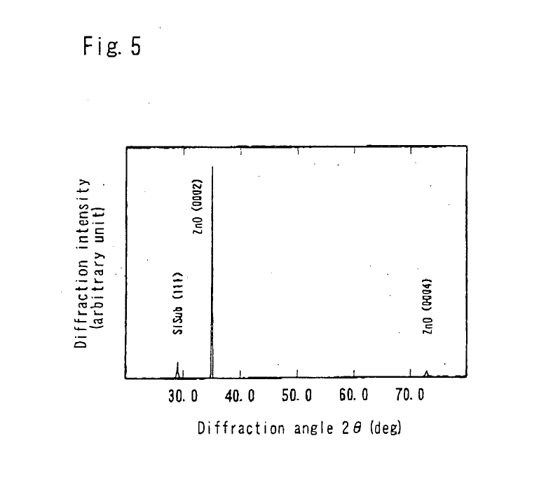

The inventor of the present invention has made an extensive study, and as a result has found that by using an RF sputtering apparatus, it is possible to form an excellent crystalline thin film on silicon at a very low growth rate of about 50 Å/m under conditions of oxygen atmosphere, which makes it possible to prevent the formation of oxygen defect, and a temperature which does not always have to be high and can be as low as about 300° C. or less at which an oxide film is less likely to grow on silicon. The zinc oxide semiconductor thin film obtained under the above growth conditions is semi-insulating. FIG. 4 shows a PL emission spectrum of a zinc oxide semiconductor thin film formed by the present inventor, and FIG. 5 shows an X-ray diffraction diagram of the zinc oxide semiconductor thin film. As can be seen from FIG. 4, the zinc oxide semiconductor thin film exhibits clear band-edge emission at a wavelength of 375 nm, and as can be seen from the X-ray diffraction diagram of FIG. 5, the zinc oxide semiconductor thin film has an excellent C axis orientation. Such an excellent semi-insulating ZnO thin film 3 is formed on the entire surface of the wafer as shown in FIG. 3B. At this time, the sputtering apparatus does not always have to be used. The semi-insulating ZnO thin film 3 can also be formed by using, for example, an MBE apparatus or a laser ablation apparatus under optimum conditions.

As shown in FIG. 3C, the semi-insulating ZnO thin film 3 formed in the production step shown in FIG. 3B is etched into a desired shape (e.g., so as to be slightly overlapped with the oxide film pattern). Then, the semi-insulating ZnO thin film 3 is preferably subjected to annealing at a temperature, at which roughening of the surface thereof does not occur, to stabilize the interface between silicon and zinc oxide and to improve characteristics resulting from a pn-junction, such as a leakage current. By using such a simple process shown in FIGS. 3A to 3C, it is possible to form a p-type inversion layer 4 in the upper part of the n-type silicon 1 which is in contact with the semi-insulating ZnO thin film 3, and the thus formed p-type inversion layer 4 constantly exists as a light-receiving region.

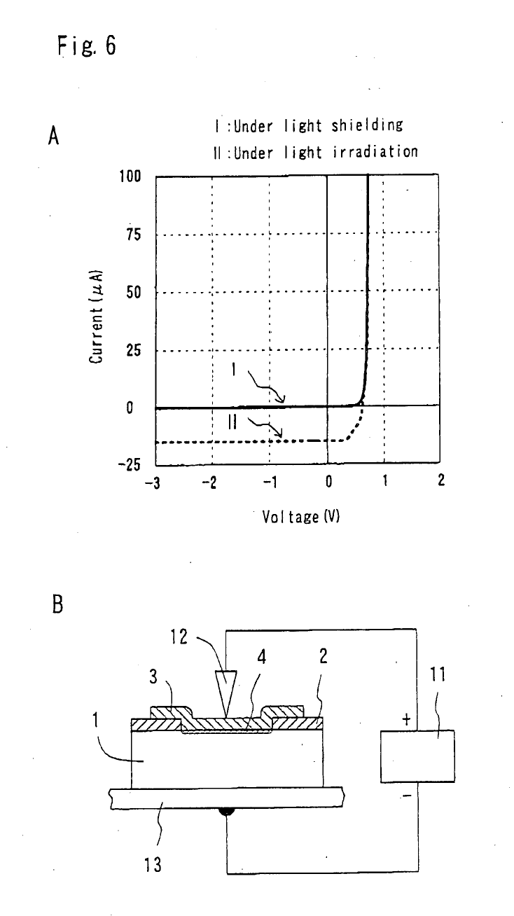

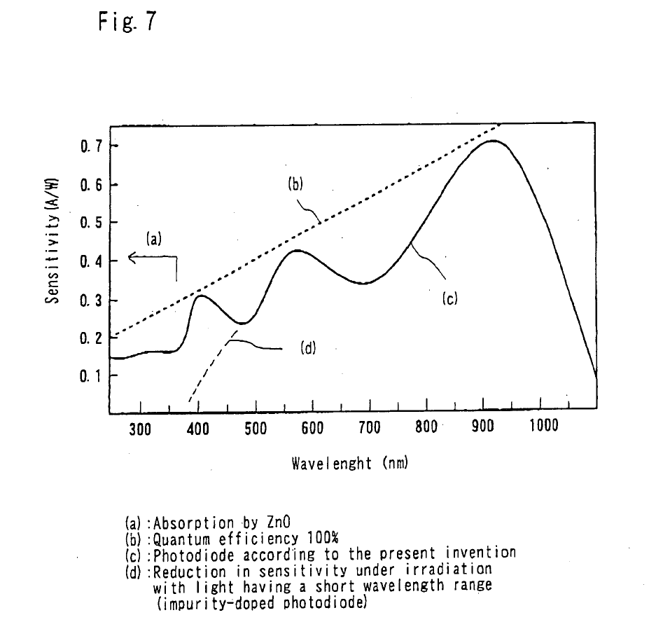

FIG. 6A is a graph which shows an example of characteristics of the thus formed pn-junction having an inversion layer as a p-type region. The semi-insulating ZnO thin film 3 is almost insulating, and therefore it is difficult to obtain good ohmic contact unless the semi-insulating ZnO thin film 3 is doped with p-type impurities. For this reason, the graph shown in FIG. 6A was made by measuring the characteristics of the pn-junction with a curve tracer 11 after the following operations: as shown in FIG. 6B, the photodiode was placed on a suction stage 13, and a probe needle 12 made of, for example, tungsten was directly brought into contact with the semi-insulating ZnO thin film 3, and the insulation of the semi-insulating ZnO thin film 3 was broken by, for example, applying a forward bias of about several to 50 V thereto to forcibly bring the semi-insulating ZnO thin film 3 into forward conduction. As can be seen from FIG. 6A, the photodiode exhibited excellent rectifying characteristics as in the case of a conventional pn-junction formed by doping in spite of the fact that the insulation of the semi-insulating ZnO thin film 3 was broken to bring it into conduction. This is because the p-type inversion layer 4 is formed not by an external electric field or polarization but by valence band discontinuity, and therefore can exist constantly and stably. Further, as can be seen from FIG. 6A, when the p-type inversion layer 4 serving as a light-receiving region was irradiated with light, the photodiode showed good response to light although the characteristics of the photodiode was slightly changed due to, for example, contact resistance. FIG. 7 is a graph which shows an example of spectral sensitivity characteristics of the photodiode according to the first embodiment of the present invention.

As can be seen from the graph shown in FIG. 7, the sensitivity of a conventional impurity-doped photodiode is rapidly decreased in a short-wavelength region, whereas the photodiode according to the present invention shows a sensitivity of 0.3 Å/W or higher (a quantum conversion efficiency of 95% or higher) to blue-violet light having a wavelength of 400 nm. In addition, the photodiode according to the present invention shows spectral characteristics substantially parallel to a straight line corresponding to a quantum efficiency of 100% under irradiation with light having a long wavelength while interference by zinc oxide and air occurs, and has a very high quantum efficiency. This is because zinc oxide is transparent to light having a wavelength exceeding a band-edge wavelength of 375 nm, and unlike the conventional impurity-doped photodiode, the lifetime of carriers generated by light is not affected by acceptor ions generated by impurity doping. In addition, as can be seen from FIG. 7, the photodiode according to the present invention shows high sensitivity characteristics under irradiation with light having a wavelength shorter than a band-edge wavelength of 375 nm because the zinc oxide thin film absorbs such light.

As described above with reference to FIG. 6B, in the case of the photodiode according to the first embodiment of the present invention, it is necessary to forcibly bring the semi-insulating ZnO thin film 3 into conduction in a direction from the above to bottom of the semi-insulating ZnO thin film 3, which is not always preferred. Further, it is also necessary to make a part of the semi-insulating ZnO thin film 3 p-type to obtain an ohmic electrode from the semi-insulating ZnO thin film 3, which is very difficult at the present time.

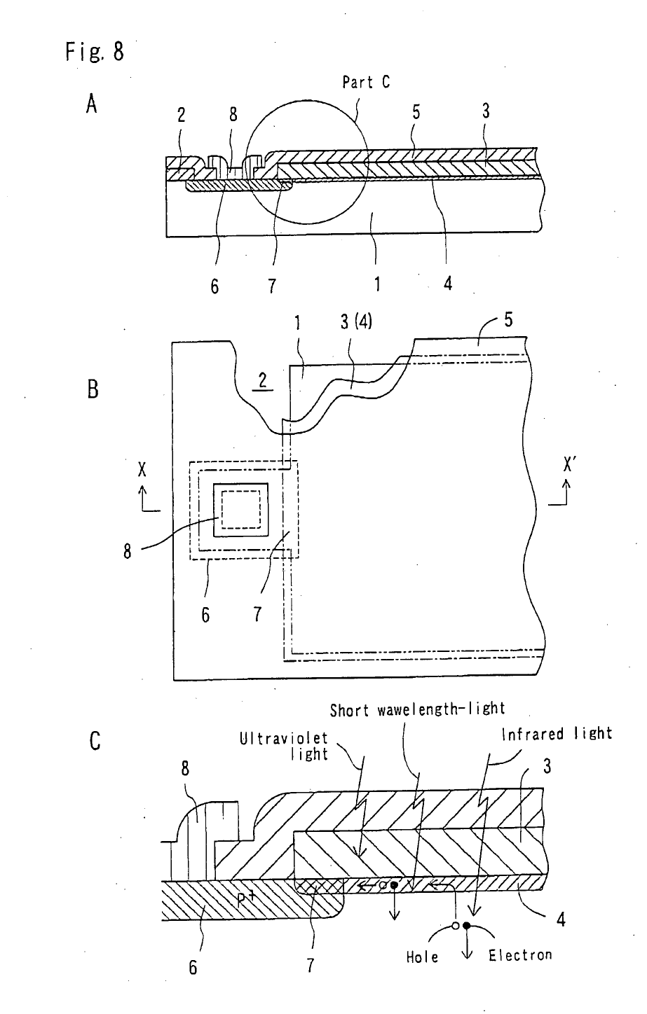

FIGS. 8A to 8C show a photodiode according to a second embodiment of the present invention having an impurity-doped region formed so as to overlap with a p-type inversion layer serving as a light-receiving region. As shown in FIG. 8A, a semi-insulating ZnO thin film 3 is formed on n-type silicon 1, a p-type inversion layer 4 is formed as a light-receiving region, and the p-type inversion layer 4 has an overlapping area 7 with a p-type impurity-doped region 6, thereby allowing the p-type impurity-doped region 6 to function as an ohmic contact region. FIG. 8B is a plan view which schematically shows the photodiode according to the second embodiment of the present invention. FIG. 8A is a cross section taken along line X-X′ shown in FIG. 8B. FIG. 8C is an enlarged view of a part C shown in FIG. 8A. The operation of the photodiode according to the second embodiment of the present invention will be described with reference to FIG. 8C.

When light having a relatively long wavelength, such as red light, enters the photodiode according to the present invention, the light deeply penetrates the silicon substrate to a depth of several tens of microns as in the case of a conventional photodiode so that electron-hole pairs are generated. Then, as shown in FIG. 8C, holes as minority carriers move toward the p-type inversion layer 4 along an electric field. The holes become majority carriers in the p-type inversion layer 4 and form a hole flow. Since the p-type inversion layer 4 is formed by the inversion of high-resistance n-type silicon doped with a small amount of impurities, scattering of carriers by donor ions is suppressed. In addition, since acceptor ions for forming a p-type region are not present, scattering of carriers by acceptor ions does not occur. As shown in FIG. 2C, since the holes are confined in a potential barrier in a direction perpendicular to the hetero-interface between the semi-insulating ZnO thin layer 3 and the n-type silicon, the holes behave like two-dimensional holes which can move only in a plane parallel to the interface. As a result, the holes can have a much higher mobility than those in a conventional impurity-doped pin photodiode, thereby enabling fast response to be achieved.

On the other hand, when light having a short wavelength, such as blue light, enters the photodiode according to the second embodiment, as in the case of the photodiode according to the first embodiment, the p-type inversion layer 4 serving as a light-receiving region directly receives the light passing through the semi-insulating ZnO thin film 3 which is transparent to visible light. Unlike a conventional impurity-doped photodiode, since the light is received by the light-receiving which is not doped with any impurities, scattering of carriers by acceptor ions does not occur and therefore a very high light-receiving sensitivity which is almost equal to a theoretical value can be achieved. In addition, as in the case of infrared light, a hole flow generated by receiving blue light is not scattered by acceptor ions in the p-type inversion layer 4 because acceptor ions are not present (i.e., two-dimensional hole effect), thereby enabling fast response to be achieved.

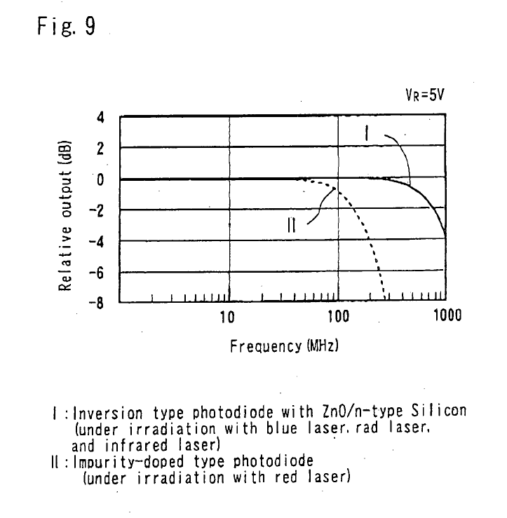

FIG. 9 shows the frequency characteristics of a conventional impurity-doped photodiode and the photodiode according to the second embodiment of the present invention under irradiation with laser light. In this regard, it is to be noted that the conventional impurity-doped photodiode and the photodiode according to the second embodiment of the present invention have the same light-receiving diameter of 600μφ and the same wafer specifications. The conventional impurity-doped photodiode has a low sensitivity to blue light, and therefore FIG. 9 shows the frequency characteristics of the conventional impurity-doped photodiode under irradiation with a red laser (650 nm), and at this time, a frequency at which the output is reduced by 3 dB, that is, fc is 180 MHz. On the other hand, when irradiated with a blue-violet laser (405 nm), a red laser (650 nm), and an infrared laser (780 nm), the photodiode having a p-type inversion layer formed using zinc oxide exhibits the same frequency characteristics as can be shown by the same curve, and fc is significantly increased to 900 MHz. As described above, the conventional impurity-doped photodiode and the photodiode according to the second embodiment are significantly different in frequency characteristics in spite of the fact that they have the same wafer specifications because the mobility of holes in the p-type inversion layer region of the photodiode according to the second embodiment is high.

The photodiode according to the second embodiment of the present invention has the same spectral characteristics as the photodiode according to the first embodiment of the present invention (see FIG. 7). Also in the case of the photodiode according to the second embodiment of the present invention, ultraviolet light having a wavelength less than a band-edge wavelength of 375 nm is received by the zinc oxide layer, and then photoelectric conversion is performed highly efficiently. As described above, the photodiode according to the present invention can achieve fast response while having a light-receiving spectrum in a wide wavelength range from ultraviolet to infrared.

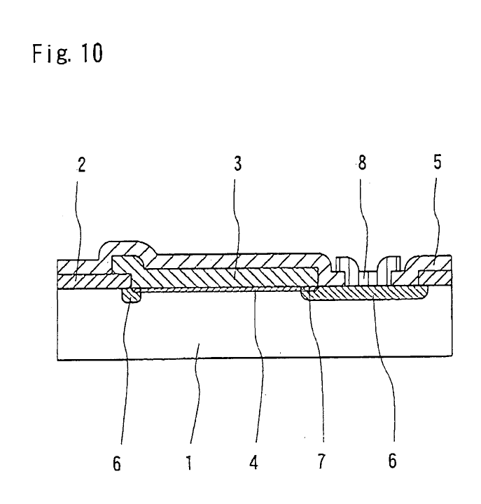

In the photodiode according to the second embodiment of the present invention shown in FIG. 8, the p-type impurity-doped region 6 is formed in a limited area. However, in a case where the area of a light-receiving region is large, as shown in FIG. 10 (which illustrates a photodiode according to a third embodiment of the present invention), the p-type impurity-doped region 6 is preferably formed into a ring shape so as to surround the outer portion of the p-type inversion layer 4 because carriers present in the center of the p-type inversion layer 4 can be transferred to the electrode in a shorter time and therefore a response speed becomes higher.

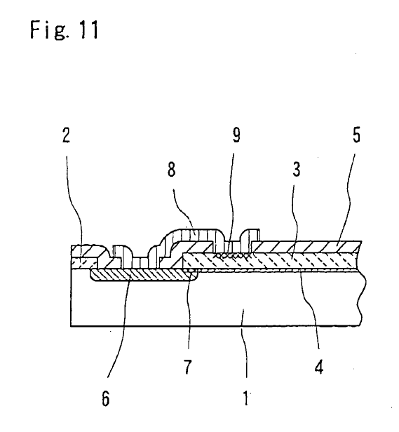

FIG. 11 illustrates a photodiode according to a fourth embodiment of the present invention which is designed to prevent the p-type inversion layer 4 from being destabilized due to, for example, polarization of the semi-insulating ZnO thin film 3. Since ZnO has piezoelectricity, it can be considered that when the semi-insulating ZnO thin film 3 is insulating, it is very easily polarized. In order to prevent the polarization of the semi-insulating ZnO thin film 3, the resistance of the semi-insulating ZnO thin film 3 is partially reduced to provide an n⁺ region 9 having a resistance of 1 kΩ/□ or less, and an anode electrode 8 is formed so that the n⁺ region 9 can be connected to the p-type impurity-doped region 6 via the anode electrode 8. The n⁺ region 9 having a low resistance can be formed by doping with, for example, Al or Ga or by reduction.

Such a structure makes it possible to fix the surface potential of the semi-insulating ZnO thin film 3, thereby stabilizing reverse characteristics. This effect will be described with reference to Table 1. Table 1 shows an example of characteristics of the photodiode having the value of a dark current at the time when a reverse voltage V_{R} was 5 V. When the electric potential of the semi-insulating ZnO thin film 3 was not fixed, a dark current was as large as 10 nA or more. On the other hand, when the electric potential of the semi-insulating ZnO thin film 3 was fixed to an anodic potential, a dark current was as small as about 10 pA, that is, a dark current was significantly decreased by a factor of about 1000. The same goes for a reverse withstand voltage. A photodiode whose n substrate had a specific resistance of 1.5 kΩ-cm was experimentally produced. When the electric potential was not fixed, a reverse withstand voltage (BV_{R}) greatly varied within a range of 5 to 150 V. On the other hand, when the electric potential was fixed, a reverse withstand voltage was stabilized at around 150 V, that is, original performance data.

TABLE 1
VR = 5 V

| | 1 | 2 | 3 | 4 | 5 |
|---|---|---|---|---|---|
| Case where surface | 10 pA | 9 pA | 24 pA | 9 pA | 8 pA |
| potential of ZnO was | | | | | |
| fixed to anodic | | | | | |
| potential | | | | | |
| Case where surface | 25 nA | 17 nA | 60 pA | 0.7 nA | 13 nA |
| potential of ZnO was | | | | | |
| not fixed to anodic | | | | | |
| potential | | | | | |

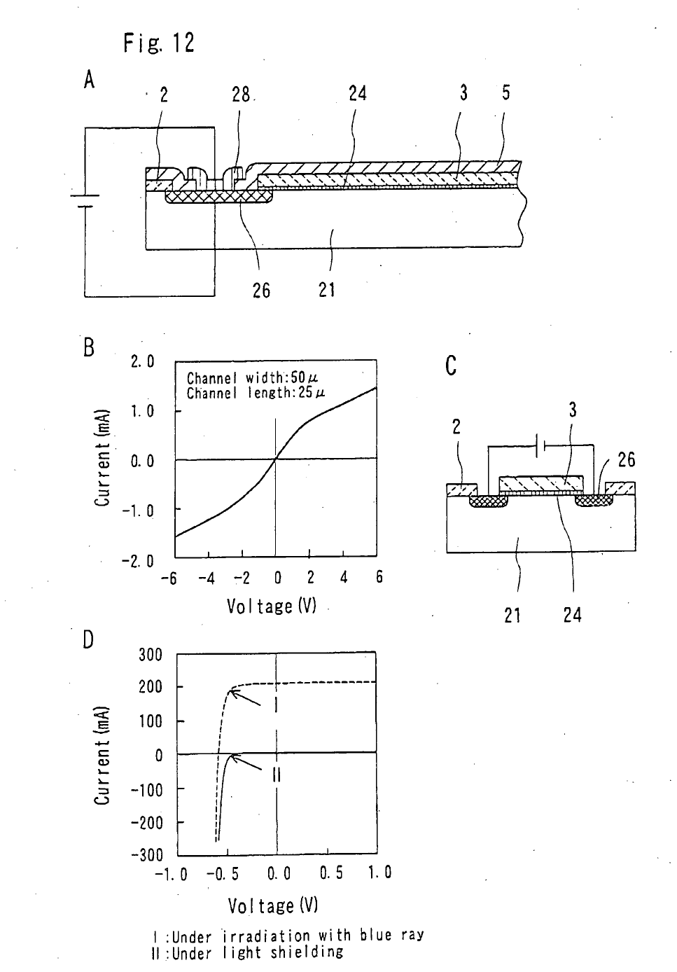

FIG. 12A is a cross-sectional view of a photodiode according to a fifth embodiment of the present invention using p-type silicon 21. As shown in FIG. 12A, an n-type channel layer 24 is formed in the lowest part of the semi-insulating ZnO thin film 3. It can be considered that the n-type channel layer 24 is formed by band discontinuity (ΔEc) between the semi-insulating ZnO and silicon shown as a part D in FIG. 2B. Whether or not the n-type channel layer 24 is actually present can be determined by FIG. 12B.

FIG. 12B shows the V-I characteristics between n-type impurity-doped regions 26 shown in FIG. 12C. As shown in FIG. 12C, the n-type channel layer 24 is provided between the n-type impurity-doped regions 26. A current between the n-type impurity-doped regions 26 corresponds to a current between a source and a drain between which a gate electrode is not present. As can be seen from FIG. 12B, a channel current apparently flows. This indicates the existence of the n-type channel layer 24 formed in the lowest part of the semi-insulating ZnO thin film 3. As shown in FIG. 12A, in the photodiode according to the fifth embodiment of the present invention using p-type silicon, the n-type channel layer 24 formed in the lowest part of the semi-insulating ZnO thin film 3 and the p-type silicon provide a structure like a pn-junction. Therefore, the photodiode according to the fifth embodiment of the present invention can have photodiode characteristics by extracting a current from the n-type impurity-doped regions 26.

FIG. 12D shows the optical response of the photodiode shown in FIG. 12A, which was measured using a connection wiring shown in FIG. 12A under irradiation with a blue laser. As can be seen from FIG. 12D, the photodiode using p-type silicon exhibits better characteristics than the photodiode using n-type silicon. Also in the case of the photodiode using p-type silicon shown in FIG. 12A, the light-receiving region thereof is not doped with any impurities. Therefore, the photodiode using p-type silicon can have almost the same high sensitivity and excellent frequency characteristics as the photodiode using n-type silicon and having a p-type inversion layer. It is to be noted that also in the case of a photodiode using n-type silicon, such as the photodiode according to the first embodiment of the present invention shown in FIG. 1, it can be considered that an n-type channel layer is present in the lowermost part of the semi-insulating ZnO thin film 3, but drawings showing a photodiode using n-type silicon omit such an n-type channel layer.

### INDUSTRIAL APPLICABILITY

According to the present invention, it is possible to provide a photodiode using a p-type inversion layer provided, in the upper part of n-type silicon, by forming a semi-insulating zinc oxide semiconductor thin film on the n-type silicon, and a photodiode using a hetero-junction between p-type silicon and a semi-insulating zinc oxide semiconductor. These photodiodes according to the present invention have the following effects (1) to (7) when compared to a conventional impurity-doped photodiode.

(1) Since the light-receiving region can be formed without doping p-type silicon or n-type silicon with impurities, carriers generated by light are not scattered by acceptor ions or donor ions, and therefore a quantum efficiency close to 100% can be achieved under irradiation with blue light.

(2) Since the zinc oxide semiconductor thin film absorbs ultraviolet light, a high sensitivity to ultraviolet light can be achieved.

(3) Since zinc oxide is transparent to light having a wavelength of blue light or longer, the photodiode according to the present invention can have spectral characteristics along a straight line corresponding to a quantum efficiency of 100%.

(4) As described in (1) to (3), the photodiode according to the present invention can have a high sensitivity to light having a wavelength in a wide range from ultraviolet to infrared.

(5) As described above, since the light-receiving region can be formed without doping p-type silicon and n-type silicon with impurities, carriers are not scattered by acceptor ions or donor ions and therefore behave like two-dimensional carriers. This makes it possible for the photodiode according to the present invention to have much higher frequency characteristics in a wavelength range from blue-violet to infrared as compared to a conventional impurity-doped photodiode. Particularly, it has been considered very difficult for a photodiode for a blue laser to have both a high sensitivity and high frequency characteristics, but the present invention can solve such a problem and greatly contribute to widespread use of a blue laser.

(6) The light-receiving region can be formed by a very simple process, that is, by simply forming exactly the same semi-insulating zinc oxide on silicon irrespective of whether the silicon is p-type or n-type. Therefore, when high-performance photodiodes are integrated into an IC, very high flexibility can be achieved irrespective of the type of integrated circuit (e.g., bipolar, CMOS).

(7) Zinc oxide is not only cheap but also friendly to the environment, and is therefore very suitable as an industrial material.

1. A photodiode having a hetero-junction between a semi-insulating zinc oxide semiconductor thin film and silicon, comprising:
n-type silicon; and
a semi-insulating zinc oxide semiconductor thin film formed on the n-type silicon and containing neither impurities for p-type nor impurities for n-type, wherein the n-type silicon serves as a cathode region and includes, in the upper part thereof, a p-type inversion layer formed using the semi-insulating zinc oxide semiconductor thin film, wherein the p-type inversion layer serves as a light-receiving region and an anode region.

2. The photodiode having a hetero-junction between a semi-insulating zinc oxide semiconductor thin film and silicon according to claim 1, wherein the p-type inversion layer serving as a light-receiving region has an overlapping area with a p-type impurity-doped region which serves as an ohmic region for the light-receiving region.

3. The photodiode having a hetero-junction between a semi-insulating zinc oxide semiconductor thin film and silicon according to claim 2, wherein the semi-insulating zinc oxide semiconductor thin film is partially composed of low-resistance zinc oxide, and wherein the low-resistance zinc oxide is connected to the p-type impurity-doped region via an electrode formed for the low-resistance zinc oxide.

4. A photodiode having a hetero-junction between a semi-insulating zinc oxide semiconductor thin film and silicon, comprising:
p-type silicon; and
a semi-insulating zinc oxide semiconductor thin film formed on the p-type silicon and containing neither impurities for p-type nor impurities for n-type, wherein the semi-insulating zinc oxide semiconductor thin film and the p-type silicon form a hetero-junction therebetween which serves as a light-receiving region, wherein the light-receiving region has an overlapping area with an n-type impurity-doped region formed in the p-type silicon to extract a photocurrent therefrom.
